(19) United States
(12) Patent Application Publication
(10) Pub. No.: US 2026/0180473 A1
(43) Pub. Date: Jun. 25, 2026

(54) MEMS CONTROLLER AND MEMS DEVICE

(71) Applicant: AAC Kaitai Technologies (Wuhan) CO., LTD., Wuhan (CN)

(72) Inventors: Linxin Zhang, Wuhan (CN); Qiang Dan, Wuhan (CN); Yang Li, Wuhan (CN)

(21) Appl. No.: 19/342,716

(22) Filed: Sep. 29, 2025

Related U.S. Application Data
(63) Continuation of application No. PCT/CN2024/141903, filed on Dec. 24, 2024.

(51) Int. Cl. H02N 1/00; B81B 7/00; F28F 9/22; H04R 19/02

(52) U.S. Cl. CPC H02N 1/006; B81B 7/0061; F28F 9/22; B81B 2201/0257; B81B 2203/0118; B81B 2203/0307; H04R 19/02; H04R 2201/003

(57) ABSTRACT

Provided are a MEMS controller and a MEMS device. The MEMS controller includes: at least one control unit including: two adjacent first anchor structures with a gap formed therebetween; cantilever beam structures respectively corresponding to the two first anchor structure, a first end of each of the cantilever beam structures being located at a top surface of a corresponding first anchor structure, and second ends of two adjacent cantilever beam structures directly facing each other and forming a second gap therebetween; and a diaphragm covering top surfaces of two second anchor point structures; and an encapsulation structure including a bottom plate, a side plate and a top plate connected in sequence. The bottom plate is provided with a first flow channel port, penetrating through the bottom plate, corresponding to the control unit and connected to the first gap of the corresponding control unit.

### TECHNICAL FIELD

The present disclosure relates to the field of controllers, and in particular, to a MEMS controller and a MEMS device.

### BACKGROUND

A Micro-Electro-Mechanical System (MEMS), also known as micro-electro-mechanical system or microsystem, refers to a high-tech device with a size of several millimeters or even smaller, and its internal structure is generally in a micrometer level or even a nanometer level. The MEMS is an independent intelligent system developed based on microelectronics technology (semiconductor manufacturing technology), integrating technologies such as lithography, corrosion, thin film, LIGA (Lithographie, Galvanoformung, Abformung), silicon micromachining, non-silicon micromachining and precision machining.

The MEMS technology is widely used in various fields, which includes, but is not limited to: a consumer electronics product, such as a micro speaker and a MEMS microphone. Such products are widely used in laptops, smart phones and other devices due to its advantages such as a small size, low power consumption and batch manufacturing.

At present, a MEMS controller needs to be provided to control unidirectional movement of a fluid.

### SUMMARY

The present disclosure provides a MEMS controller and a MEMS device, which can at least control unidirectional movement of a fluid.

In an aspect, an embodiment of the present disclosure provides a MEMS controller, including: at least one control unit, the at least one control unit including: two first anchor structures, a first gap being formed between two adjacent first anchor structures, and each of the two first anchor structures including a bottom surface and a top surface opposite to each other; two cantilever beam structures respectively corresponding to the two first anchor structures, each of the two cantilever beam structures including a first end and a second end opposite to each other, the first end of each of the two cantilever beam structures being located at the top surface of the first anchor structure corresponding thereto, and a second gap being formed between the second ends of the two cantilever beam structures; two second anchor point structures, one second anchor point structure of the two second anchor point structures being in contact with one of the two first anchor structures, and the other one of the two second anchor point structures being located at a side of the one second anchor point structure away from the two first anchor structures; and a diaphragm covering top surfaces of the two second anchor point structures; and an encapsulation structure including a bottom plate, a side plate and a top plate connected in sequence, the bottom plate facing the top plate, and the side plate connecting the bottom plate and the top plate. The bottom plate is located at the bottom surfaces of the two first anchor structures and the two second anchor point structures, the bottom plate is provided with a flow channel port penetrating through the bottom plate, the first flow channel port corresponds to the control unit, the first flow channel port is in communication with the first gap of the corresponding control unit; and the top plate is spaced apart from the top surfaces of the two cantilever beam structures and the diaphragm, and the top plate is provided with a second flow channel port penetrating through the top plate, and the second flow channel port corresponds to the control unit.

As an improvement, in one control unit, a vibration frequency of at least one of the two cantilever beam structures is the same as a vibration frequency of the diaphragm, and an initial phase of the at least one of the two cantilever beam structures is different from an initial phase of the diaphragm.

As an improvement, a distance between a center of the second flow channel port and the second end of the cantilever beam structure close to the second flow channel port is within a range from 100 μm to 5000 μm.

As an improvement, a height of one of the two first anchor structures is the same as a height of one of the two second anchor point structures.

As an improvement, a height of one of the two second anchor point structures is within a range from 100 μm to 5000 μm.

As an improvement, a thickness of one of the two cantilever beam structures is equal to a thickness of the diaphragm.

As an improvement, the at least one control unit includes two or more control units, and the two second anchor point structures in one of the control units are in contact with the two first anchor structures of an adjacent one of the control units.

As an improvement, the at least one control unit includes two or more control units, one of the two second anchor point structures in one control unit is in contact with the first anchor structure, and the other one of the two second anchor point structures in the one of the control units is in contact with the second anchor point structure of an adjacent one of the control units.

In an aspect, an embodiment of the present disclosure provides a MEMS device, including the MEMS controller described above.

The technical solutions provided by the embodiments of the present disclosure have at least the following advantages. When the MEMS device is used as a part of a heat dispersing device, the diaphragm vibrates to suck cooling fluid from one of the first flow channel port or the second flow channel port, and then the fluid flows through the gap between the cantilever beam structures and flows out from the other one of the first flow channel port or the second flow channel port, thereby achieving unidirectional flowing control of the gas. When the MEMS device is used as a part of a speaker, the diaphragm vibrates to generate a high-frequency signal, and a sound channel surrounded by the encapsulation structure, the cantilever beam structure, the first anchor point structure and the diaphragm can achieve the demodulation of the high-frequency signal, so as to convert the high-frequency signal to be a low-frequency signal, and output a human-audible sound frequency. The encapsulation structure serves as a protective shell of the control unit and encloses the control unit to form a flow channel, thereby facilitating the output of the cooling fluid or the demodulation of the sound.

### BRIEF DESCRIPTION OF DRAWINGS

One or more embodiments are exemplarily illustrated by the corresponding figures in the accompanying drawings, and are not intended to limit the embodiments. Unless otherwise specified, the figures in the accompanying drawings do not provide a scale limit. To better illustrate the technical solutions in the embodiments of the present disclosure or in the conventional technical means, a brief introduction to the accompanying drawings required in the embodiments will be provided below. It should be noted that the accompanying drawings described below are merely some embodiments of the present disclosure. For those skilled in the art, other drawings may be obtained based on these accompanying drawings without any creative efforts.

FIG. 1 is a schematic diagram of a structure of a MEMS controller according to an embodiment of the present disclosure;

FIG. 2 is a curve diagram of the relationship between a height of a second anchor point structure and a flow rate per unit chip volume according to an embodiment of the present disclosure;

FIG. 3 is a diagram of a relationship between a first distance and a flow rate per unit chip volume according to an embodiment of the present disclosure;

FIG. 4 is an arrangement manner of a control unit according to an embodiment of the present disclosure;

FIG. 5 is another arrangement manner of a control unit according to an embodiment of the present disclosure;

FIG. 6 is another arrangement manner of a control unit according to an embodiment of the present disclosure;

FIG. 7 is a schematic diagram of a structure of a first flow channel port as an outlet of a fluid;

FIG. 8 is a schematic diagram of a structure of a second flow channel port as an outlet of a fluid;

FIG. 9 is a time domain diagram of a displacement of a center of a diaphragm;

FIG. 10 is a time domain diagram of a flow rate of a fluid flowing out from a second flow channel port;

FIG. 11 is a schematic diagram of a structure of a second flow channel port as a sound outlet;

FIG. 12 is a schematic diagram of a structure of a first flow channel port as a sound outlet;

FIG. 13 is a spectrum diagram of an ultrasonic signal generated by a diaphragm;

FIG. 14 is a spectrum diagram of a sound pressure at the sound outlet; and

FIG. 15 is a schematic diagram of a simulation structure of a loudspeaking process.

### DESCRIPTION OF EMBODIMENTS

As can be known from the background technology, it is currently necessary to provide a MEMS controller to control the unidirectional flow of a fluid.

An embodiment of the present disclosure provides a MEMS controller and a MEMS device. When the MEMS device is used as a part of a heat dispersing device, the diaphragm vibrates to suck cooling fluid from one of the first flow channel port or the second flow channel port, and then the fluid flows through the gap between the cantilever beam structures and flows out from the other one of the first flow channel port or the second flow channel port, thereby achieving unidirectional flowing control of the gas. When the MEMS device is used as a part of a speaker, the diaphragm vibrates to generate a high-frequency signal, and a sound channel surrounded by the encapsulation structure, the cantilever beam structure, the first anchor point structure and the diaphragm can achieve the demodulation of the high-frequency signal, thereby converting the high-frequency signal to be a low-frequency signal, to output a human-audible sound frequency. The encapsulation structure serves as a protective shell of the control unit and surrounds a flow channel, thereby facilitating the output of the cooling fluid or the demodulation of the sound.

In the description of the embodiments of the present disclosure, the technical terms “first”, “second”, etc. are only used to distinguish different objects, and should be understood as indicating or implying relative importance or implicitly indicating the number, specific order or primary and secondary relationship of the indicated technical features. In the description of the embodiments of the present disclosure, the meaning of “multiple/a plurality of” refers to more than two, unless otherwise clearly and specifically defined.

Reference to “embodiments” herein means that a particular feature, structure, or characteristic described in conjunction with the embodiments may be included in at least one embodiment of the present disclosure. The appearance of this phrase in various places in the specification does not necessarily refer to a same embodiment, nor is it an independent or alternative embodiment that is mutually exclusive with other embodiments. It is explicitly and implicitly understood by those skilled in the art that an embodiment described herein may be combined with other embodiment.

In the description of the embodiments of the present disclosure, the term “and/or” is only a description of the association relationship of associated objects, indicating that three relationships may exist. For example, A and/or B may represent: A exists alone, A and B exist at the same time, and B exists alone. In addition, the character “/” in the specification generally indicates that the associated objects prior to and subsequent to the character “/” are in an “or” relationship.

In the description of the embodiments of the present disclosure, the term “multiple/a plurality of” refers to more than two (including two). Similarly, “multiple/a plurality of groups” refers to more than two groups (including two groups), and “multiple/a plurality of pieces” refers to more than two pieces (including two pieces).

In the description of the embodiments of the present disclosure, the technical terms “center”, “longitudinal”, “lateral”, “length”, “width”, “thickness”, “up”, “down”, “front”, “back”, “left”, “right”, “vertical”, “horizontal”, “top”, “bottom”, “inside”, “outside”, “clockwise”, “counterclockwise”, “axial”, “radial”, “circumferential”, and the like indicate orientations or positions based on the orientations or positions shown in the accompanying drawings, and are only for the convenience of describing the embodiments of the present disclosure and simplifying the description, and do not indicate or imply that the referred device or element must have a specific orientation, be constructed and operated in a specific orientation, and therefore should not be understood as limiting the embodiments of the present disclosure.

In the description of the embodiments of the present disclosure, unless otherwise clearly specified and limited, technical terms such as “installation”, “coupling”, “connection”, “fixation” and the like should be understood in a broad sense, for example, it can be a fixed connection, a detachable connection, or an integral connection; it can be a mechanical connection or an electrical connection; it can be a direct connection or an indirect connection through an intermediate medium; it can be an internal connection of two elements or an interaction relationship between two elements. For ordinary skilled in the art, the specific meanings of the above-mentioned terms in the embodiments of the present disclosure can be understood according to specific circumstances.

In the accompanying drawings corresponding to the embodiments of the present disclosure, a thickness and an area of a layer is exaggerated for better illustration and ease of description. When describing one component (such as a layer, a film, a region or a lens body) at another one component or at a surface of another one component, the one component may be “directly” located at the surface of another one component, or a third component may exist between the two components. On the contrary, when describing one component on a surface of another one component or when another one component is formed or provided on a surface of one component, it means that there is no third component between the two components. In addition, when describing one component “substantially” formed at another one component, it means that the one component is not formed at an entire surface (or a front surface) of another one component, nor is it formed at a partial edge of the entire surface.

In the description of the embodiments of the present disclosure, when describing that one component “includes” another one component, unless otherwise specified, other components are not excluded, and other components may be further included. In addition, when describing that one component such as a layer, film, region, or plate is located at/on another one component, the one component can be “directly located at” another one component (i.e., located on a surface of another one component without other components therebetween), or another component may exist therebetween. In addition, when describing that one component such as a layer, film, region, or plate is “directly located at” another one component, or when describing that one component such as a layer, film, region, or plate is located on a surface of another one component, it means that no other components are located therebetween.

The terms used in the description of the various embodiments described herein are only used to describe specific embodiments and are not intended to limit thereto. As used in the description of the various embodiments described herein and in the appended claims, “the component” is also intended to include plural forms unless the context clearly indicates otherwise. Herein, the component may include a component such as a layer, a film, a region, or a plate.

The following will describe the various embodiments of the present disclosure in detail with reference to the accompanying drawings. However, it will be appreciated by those skilled in the art that, in the various embodiments of the present disclosure, many technical details are provided in order to enable the reader to better understand the present disclosure. However, even without these technical details and various changes and modifications based on the following embodiments, the technical solutions claimed in the present disclosure can be implemented.

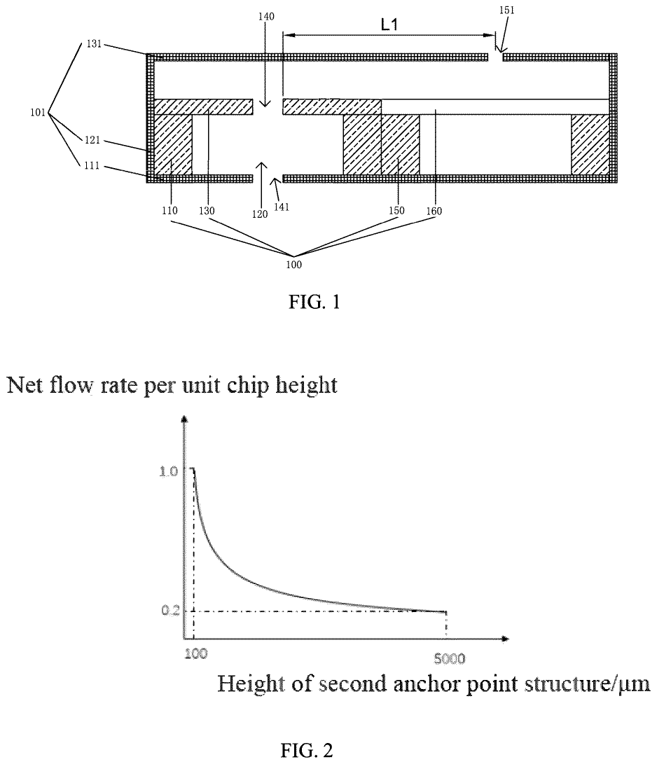

FIG. 1 is a schematic diagram of a structure of a MEMS controller according to an embodiment of the present disclosure.

In some embodiments, the MEMS controller may include: at least one control unit 100. The control unit 100 includes: two first anchor point structures 110, a first gap 120 being formed between adjacent first anchor point structures 110, and the first anchor point structure 110 including a bottom surface and a top surface opposite to each other; a cantilever beam structure 130 corresponding to each of the first anchor point structures 110, the cantilever beam structure 130 including a first end and a second end opposite to each other, a first end of each cantilever beam structure 130 being located at the top surface of the corresponding first anchor point structure 110, and the second ends of two adjacent cantilever beam structures 130 of the same control unit 100 directly facing each other and forming a second gap 140 therebetween; two second anchor point structures 150, one second anchor point structure 150 being in contact with one first anchor point structure 110, and the other one second anchor point structure 150 being located at a side of the one second anchor point structure 150 away from the first anchor point structure 110; and a diaphragm 160 covering the top surfaces of the two second anchor point structures 150.

The MEMS controller may further include an encapsulation structure 101. The encapsulation structure 101 includes a bottom plate 111, a side plate 121 and a top plate 131 connected in sequence. The bottom plate 111 directly faces the top plate 131. The side plate 121 connects the bottom plate 111 and the top plate 131. The bottom plate 111 is located at the bottom surfaces of the first anchor point structure 110 and the second anchor point structure 150. A first flow channel port 141 penetrating through the bottom plate 111 is formed. The first flow channel port 141 corresponds to the control unit 100, and the first flow channel port 141 is in communication with the first gap 120 of the corresponding control unit 100. The top plate 131 is spaced apart from the top surfaces of the cantilever beam structure 130 and the diaphragm 160. A second flow channel port 151 penetrating through the top plate 131 is formed. The second flow channel port 151 corresponds to the control unit 100.

An embodiment of the present disclosure provides a MEMS controller. When the MEMS device is used as a part of a heat dispersing device, the diaphragm 160 vibrates to suck cooling fluid from one of the first flow channel port 141 or the second flow channel port 151, and then the fluid flows through the gap between the cantilever beam structures 130 and flows out from the other one of the first flow channel port 141 or the second flow channel port 151, thereby achieving unidirectional flowing control of the gas. When the MEMS device is used as a part of a speaker, the diaphragm 160 vibrates to generate a high-frequency signal, and a sound channel surrounded by the encapsulation structure 101, the cantilever beam structure 130, the first anchor point structure 110 and the diaphragm 160 can achieve the demodulation of the high-frequency signal, so as to convert the high-frequency signal to be a low-frequency signal, and output a human-audible sound frequency. The encapsulation structure 101 serves as a protective shell of the control unit 100 and encloses the control unit 100 to form a flow channel, thereby facilitating the output of the cooling fluid or the demodulation of the sound.

The entire control unit can be formed by MEMS manufacturing technology or other precision technologies.

The first anchor structure 110 can be used to support the cantilever beam structure 130. The top surface of the first anchor structure 110 is fixedly connected to the first end of the cantilever beam structure 130. The first anchor structure 110, the cantilever beam structure 130 and the encapsulation structure 101 together form a flow channel, so that the fluid enters the flow channel and flows out from the second flow channel port 151 or the first flow channel port 141.

In some embodiments, the cantilever beam structure 130 may vibrate during the operation of the MEMS controller, so that the cantilever beam structure 130 can help the movement of the fluid or help the demodulation of the sound. Taking the MEMS controller needing to complete the heat dissipation function as an example, the vibration of the cantilever beam structure 130 can cooperate with the diaphragm 160 to increase a flowing rate of the fluid.

The first anchor structure 110 may drive the cantilever beam structure 130 in a manner including: piezoelectric driving, electrostatic driving, thermoelectric driving, electromagnetic driving, or the like. Taking piezoelectric driving as an example, an inverse piezoelectric effect of the piezoelectric material is used to convert electrical energy to be mechanical energy to drive the cantilever beam structure 130 to vibrate.

In some embodiments, the first anchor structure 110 may be a control layer of a Silicon-On-Insulator (SOI) chip. The first anchor structure 110 may also be a control layer of other types of chips that can cooperate to drive the cantilever beam structure 130.

In some embodiments, during the operation of the MEMS controller, one of the two first anchor structures 110 can be selected to control the vibration of the corresponding cantilever beam structure 130, or both of the two first anchor structures 110 can control the vibration of the cantilever beam structure 130. The working time or working status of the first anchor structures 110 can be selected according to different working requirements.

In some embodiments, in the same control unit 100, the vibration frequency of at least one cantilever beam structure 130 is the same as the vibration frequency of the diaphragm 160, and an initial phase of the cantilever beam structure 130 is different from an initial phase of the diaphragm 160. It can be understood that, in an example, the second flow channel port 151 serves as a fluid inlet, when the fluid is sucked into the MEMS controller due to the vibration of the diaphragm 160, since the movement of the fluid takes a certain amount of time, it takes a certain amount of time for the fluid to move above the cantilever beam structure 130, therefore, by controlling the initial phase of the cantilever beam structure 130 to be different from the initial phase of the diaphragm 160, the cantilever beam structure 130 can operate with the diaphragm 160, so that the fluid above the second gap 140 can be sucked into the cantilever beam structure 130 again, thereby completing the acceleration of the fluid to achieve improved heat dissipation effect. When the MEMS controller needs to perform loudspeaking, the demodulation of the sound can be achieved through the diaphragm 160, the sound channel structure and vibration of the cantilever beam structure 130, to achieve loudspeaking function of the MEMS controller.

In some embodiments, the initial phase of the cantilever beam structure 130 and the initial phase of the diaphragm 160 may differ by 5° or 10°, etc. It is understood that the cantilever beam structure 130 and the diaphragm 160 may be best matched when the difference between the initial phase of the cantilever beam structure 130 and the initial phase of the diaphragm 160 can be calculated through calculation and simulation.

In some embodiments, in the same control unit 100, a vibration frequency of the cantilever beam structure 130 is the same as a vibration frequency of the diaphragm 160, and the initial phase of the cantilever beam structure 130 is the same as the initial phase of the diaphragm 160. In this case, the control difficulty of the MEMS controller can be decreased, and the vibrations of the cantilever beam structure 130 and the diaphragm 160 can be controlled simultaneously by a same control signal.

In some embodiments, the initial phase of the cantilever beam structure 130 can be adjusted to control the flowing rate of the fluid flowing out through the MEMS controller. For example, when the flowing rate of the fluid is too fast, the initial phase of the cantilever beam structure 130 can be adjusted to interfere with the diaphragm 160 sucking in the fluid, thereby decreasing the rate at which the fluid flows out through the MEMS controller.

Two cantilever beam structures 130 may be controlled individually or simultaneously. During the operation of the MEMS controller, only one of the cantilever beam structures 130 may be controlled, or two cantilever beam structures 130 may be controlled to vibrate simultaneously.

In some embodiments, the vibrations of two cantilever beam structures 130 may have: a same initial phase, a same vibration frequency and a same amplitude; in some other embodiments, the vibrations of two cantilever beam structures 130 may have: a same vibration frequency, a same amplitude, and different initial phases.

In some embodiments, the cantilever beam structure 130 may bring an effect opposite to that of the diaphragm 160, for example, the flowing rate of the fluid passing through the second gap 140 may be decreased by the cantilever beam structure 130, thereby completing the control of the flowing rate of the fluid.

The cantilever beam structure 130 and the first anchor structure 110 may be support layers without any function and are only used to construct a flow channel for the fluid or a sound channel for the sound.

The second anchor point structure 150 can be used to support the diaphragm 160. The second anchor point structure 150, the first anchor structure 110, the cantilever beam structure 130 and the encapsulation structure 101 together form a flow channel, so that the fluid flows out from the second flow channel port 151 or the first flow channel port 141 through the flow channel.

The second anchor point structure 150 may drive the diaphragm 160 in a manner including: piezoelectric driving, electrostatic driving, thermoelectric driving, electromagnetic driving, or the like. Taking piezoelectric driving as an example, the inverse piezoelectric effect of the piezoelectric material can be used to convert electrical energy to be mechanical energy to drive the diaphragm 160 to vibrate.

The second anchor point structure 150 may be a control layer of a SOI chip. The second anchor point structure 150 may also be a control layer of other types of chips that can cooperate to drive the driving diaphragm 160.

In some embodiments, a height of the first anchor structure 110 is the same as a height of the second anchor point structure 150. That is, a distance between the cantilever beam structure 130 and the top plate 131 is equal to a distance between the diaphragm 160 and the top plate 131, so that when the fluid flows from the space between the diaphragm 160 and the top plate 131 into the space between the cantilever beam structure 130 and the top plate 131, the state of the fluid remains unchanged.

In some embodiments, a height of the first anchor structure 110 may be smaller than a height of the second anchor point structure 150. Since the second flow channel port 151 directly faces the diaphragm 160 and is close to the diaphragm 160, when the second flow channel port 151 is used as an inlet of the fluid, the flowing rate of the fluid entering the MEMS controller through the second flow channel port 151 is relatively large. The height of the first anchor structure 110 may set to be smaller than the height of the second anchor point structure 150, so that when the fluid flows from the space between the diaphragm 160 and the top plate 131 into the space between the cantilever beam structure 130 and the top plate 131, the speed of the fluid decreases, thereby facilitating the control of the fluid to flow out from the first flow channel port 141 at a suitable speed. When the second flow channel port 151 is used as an outlet of the fluid, since a distance between the first flow channel port 141 and the diaphragm 160 is relatively large, the flowing rate of the fluid entering the MEMS controller through the first flow channel port 141 is relatively small. The height of the first anchor structure 110 may set to be smaller than the height of the second anchor point structure 150, so that when the fluid flows from the space between the cantilever beam structure 130 and the top plate 131 into the space between the diaphragm 160 and the top plate 131, the speed of the fluid increases, thereby facilitating the control of the fluid to flow out from the second flow channel port 151 at a suitable speed.

In some embodiments, the height of the second anchor point structure 150 is within a range from 100 μm to 5000 μm, for example, 300 μm, 500 μm, 1000 μm, 1800 μm, 2500 μm, 3000 μm, 4000 μm or 4600 μm, etc. Referring to FIG. 2, which is a curve diagram of a relationship between a height of a second anchor point structure and a flow rate per unit chip volume according to an embodiment of the present disclosure, for the second anchor point structure 150, the height of the second anchor point structure 150 is positively correlated with a net flow rate of the fluid driven by the MEMS controller. That is, the larger the height of the second anchor point structure 150 is, the larger the net flow rate of the fluid that can pass through the MEMS controller is. However, the larger the height of the second anchor point structure 150 is, the larger the size of the entire MEMS controller is. Moreover, the larger the height of the second anchor point structure 150 is, the lower a net flow rate per unit chip volume is, resulting in performance waste of the second anchor point structure 150, and the smaller the height of the second anchor point structure 150 is. Although the net flow rate of the fluid that can pass through the MEMS controller may decrease, the net flow rate per unit chip volume may increase. That is, the performance utilization rate of the second anchor point structure 150 may increase. Likewise, as the height of the second anchor point structure 150 decreases, the difficulty of the formation process of the MEMS controller may increase. Therefore, the height of the second anchor point structure 150 is set to be within a range from 100 μm to 5000 μm, which improves the net flow rate per unit chip volume while taking into account the process difficulty for forming the MEMS controller.

It should be noted that the flow rate per unit chip volume here refers to: a total flow rate of the fluid output through the MEMS controller per unit time divided by a planar area of the MEMS controller.

In some embodiments, the first anchor structure 110 and the second anchor point structure 150 are formed by a same material and have a same structure, and can be formed in a same process step, thereby decreasing the process steps for forming the MEMS controller and decreasing the cost of the MEMS controller.

The vibration frequency of the diaphragm 160 is greater than or equal to 20 KHz, such as 30 KHz, 50 KHz or 100 KHz. By making the vibration frequency of the diaphragm 160 greater than or equal to 20 KHz, the flowing rate of the fluid flowing in or out through the first flow channel port 141 can be increased.

The diaphragm 160 may be shaped as a polygon, such as a rectangle, a circle or a hexagon.

In some embodiments, a thickness of the cantilever beam structure 130 is equal to a thickness of the diaphragm 160. In this way, the cantilever beam structure 130 and the diaphragm 160 can be formed in a same process step, thereby decreasing the process steps for forming the MEMS controller and decreasing the cost of the MEMS controller.

When the height of the first anchor structure 110 is equal to the height of the second anchor point structure 150, the thickness of the cantilever beam structure 130 is controlled to be equal to the thickness of the diaphragm 160, and the distance between the cantilever beam structure 130 and the top plate 131 is controlled to be equal to the distance between the diaphragm 160 and the top plate 131.

The encapsulation structure 101 can be used to protect the control unit 100, to lead out signals, or to transmit control signals to the control unit 100, thereby completing signal transmission. The encapsulation structure 101 can also be used to form a flow channel for the fluid, for example, to form a flow channel for the gas, to control the gas to enter from the first flow channel port 141 and exit from the second flow channel port 151, or to control the gas to enter from the second flow channel port 151 and exit from the first flow channel port 141.

In some embodiments, the encapsulation structure 101 may be a metal plate or a PCB, etc.

In some embodiments, the second flow channel port 151 may directly face the diaphragm 160 and offset from the second gap 140. In some other embodiments, the second flow channel port 151 may be offset from the diaphragm and directly face the second gap 140.

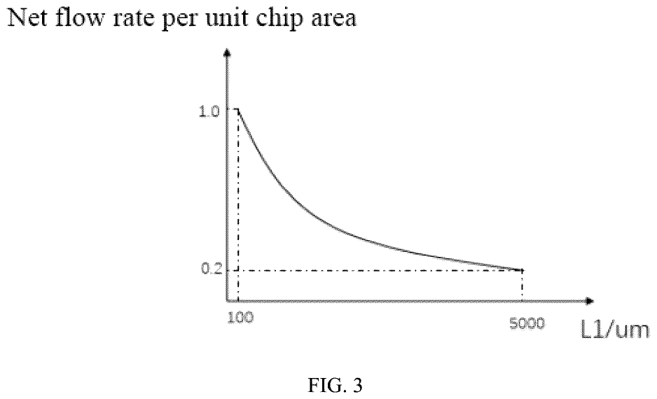

In some embodiments, a distance between a center of the second flow channel port 151 and a second end of the cantilever beam structure 130 close to the second flow channel port 151 is within a range from 100 μm to 5000 μm. The distance between the center of the second flow channel port 151 and the second end of the cantilever beam structure 130 close to the second flow channel port 151 is defined as a first distance L1. Referring to FIG. 3, which is a diagram of a relationship between a first distance and a flow rate per unit chip volume according to an embodiment of the present disclosure, for the MEMS controller, the first distance L1 is positively correlated with a net flow rate of the fluid driven by the MEMS controller. That is, the larger the first distance L1 is, the greater the net flow rate of the fluid that can pass through the MEMS controller is. However, the larger the first distance L1 is, the larger the size of the entire MEMS controller is. Moreover, the larger the first distance L1 is, the lower the net flow rate per unit chip volume is, resulting in a waste of the size of the MEMS controller; the smaller the first distance L1 is, although the net flow rate of the fluid that can pass through the MEMS controller may decrease, the net flow rate per unit chip volume may increase, that is, the volume utilization rate of the MEMS controller may increase. Similarly, as the first distance L1 decreases, the difficulty of the formation process of the MEMS controller may increase. Therefore, the first distance L1 is set to be within a range from 100 μm to 5000 μm, which can improve the net flow rate per unit chip volume while taking into account the process difficulty for forming the MEMS controller.

It should be noted that the center of the second flow channel port 151 mentioned herein may refer to a geometric center of the second flow channel port 151. If the second flow channel port 151 is shaped as a circle, the center mentioned herein refers to a center of the circle; if the second flow channel port 151 is shaped as a square, the center mentioned herein refers to an axial symmetry center of the square.

In some embodiments, the first flow channel port 141 directly faces the second gap 140. In this case, whether the fluid flows from the second gap 140 to the first flow channel port 141 or the fluid flows from the first flow channel port 141 to the second gap 140, the loss during the flowing process is decreased, and the noise during the flowing process of the fluid can also be decreased, thereby improving the performance of the MEMS controller.

In some embodiments, in an arrangement direction of the first anchor structure 110, a width of the first flow channel port 141 is greater than or equal to a width of the second gap 140. That is, in the same control unit 100, the width of the first flow channel port 141 is greater than or equal to the spacing between two cantilever beam structures 130, so that when the fluid enters from the second gap 140 and exits from the first flow channel port 141, the loss of the fluid can be decreased; and when the fluid enters from the first flow channel port 141 and exits from the second gap 140, the decrease in terms of a size of the outlet increases the kinetic energy of the fluid, thereby improving the flowing rate of the fluid.

In some embodiments, in an arrangement direction of the first anchor structure 110, a width of the second flow channel port 151 is smaller than the width of the second gap 140, and the spacing between the top plate 131 and the cantilever beam structure 130 is smaller than the spacing between the bottom plate 111 and the cantilever beam structure 130. If the second flow channel port 151 is used as an outlet for the fluid, setting the width of the second flow channel port 151 smaller can increase the speed of the fluid flowing out from the second flow channel port 151, and at the same time, setting the spacing between the top plate 131 and the cantilever beam structure 130 smaller than the spacing between the bottom plate 111 and the cantilever beam structure 130 can similarly decrease a size of the outlet of the fluid, so that the speed of the fluid outflowing from the second flow channel port 151 can be increased; if the second flow channel port 151 is used as the inlet of the fluid, setting the width of the second flow channel port 151 smaller can make the fluid have a better initial speed when entering the MEMS device, and can decrease the noise generated by the fluid in the MEMS device; at the same time, setting the distance between the top plate 131 and the cantilever beam structure 130 smaller than the distance between the bottom plate 111 and the cantilever beam structure 130 can increase the size of outlet of the fluid and thus decrease the loss and noise of the fluid in the MEMS device.

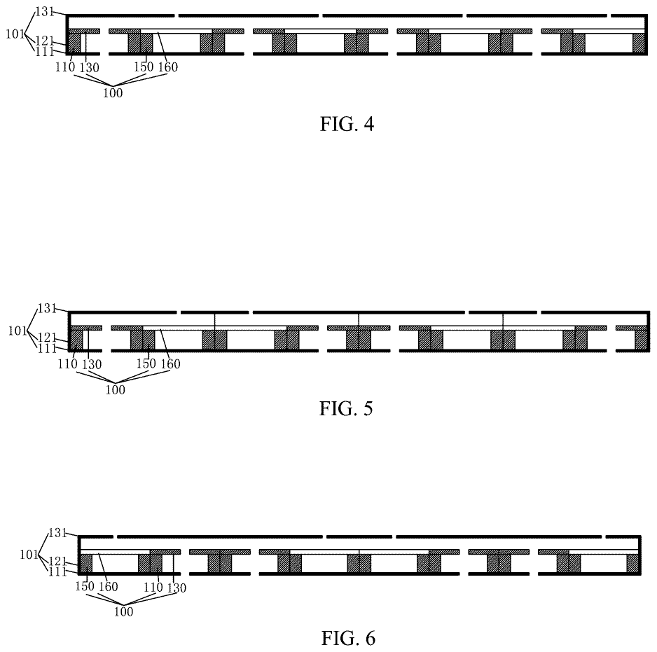

FIG. 4 is an arrangement of a control unit according to an embodiment of the present disclosure.

Referring to FIG. 1 and FIG. 4, in some embodiments, the number of control units 100 is greater than or equal to 2, and two second anchor point structures 150 in one of the control units 100 are in contact with the first anchor structure 110 of an adjacent one of the control units 100. In other words, the first anchor structure 110 and the second anchor structure in each control unit 100 are arranged in a same direction, for example, the first anchor structure 110 in each control unit 100 is located at a same side of the second anchor point structure 150, and by controlling two second anchor point structures 150 in one of the control units 100 to be contact with the first anchor structure 110 of an adjacent one of the control units 100, the process difficulty for forming the MEMS controller can be decreased.

FIG. 5 is another arrangement of a control unit according to an embodiment of the present disclosure. FIG. 6 is another arrangement of a control unit according to an embodiment of the present disclosure

Referring to FIG. 1, FIG. 5 and FIG. 6, in some embodiments, the number of control units 100 is greater than or equal to 2. For two second anchor point structures 150 in one control unit 100, one of the two second anchor point structures 150 is in contact with the first anchor structure 110, and the other one of the two second anchor point structures 150 is in contact with the second anchor point structure 150 of the other one control unit 100. In other words, the first anchor structures 110 and the second anchor point structures 150 in two adjacent control units 100 are arranged in different directions. For example, the first anchor structure 110 is located at a side of the second anchor point structure 150 in one of two adjacent control units 100, and the first anchor structure 110 is located at another side of the second anchor point structure 150 in the other one of two adjacent control units 100. For a MEMS controller including multiple control units 100, one of two second anchor point structures 150 in one control unit 100 is in contact with the first anchor structure 110, and the other one of the two second anchor point structures 150 in the one control unit 100 is in contact with the second anchor point structure 150 of the other one control unit 100, which can improve the control effect of the MEMS controller, for example, the reliability of the MEMS to control unidirectional flowing of the airflow, or the reliability of the sound demodulation of the MEMS.

Referring to FIG. 5, in some embodiments, the number of control units 100 is greater than or equal to 2, and the diaphragm 160 of the control unit 100 in contact with the side plate 121 is located at a side of the cantilever beam structure 130 away from the side plate 121, so that the inlet or outlet of the fluid can be set at a part of the MEMS controller close to a center, thereby improving the stress resistance of the encapsulation structure 101 and improving the reliability of the MEMS controller.

Referring to FIG. 6, in some embodiments, the number of control units 100 is greater than or equal to 2, and the diaphragm 160 of the control unit 100 in contact with the side plate 121 is located at a side of the cantilever beam structure 130 close to the side plate 121, so that the inlet or outlet of the fluid can be set at different parts of the MEMS controller. For example, if the fluid flows out from the second flow channel port 151, the probability that a dead angle occurs in the outflow of the fluid from the MEMS controller could be decreased.

It should be noted that the above-mentioned dead angle refers to a part that cannot be covered after the fluid flows out.

In some embodiments, the diaphragms 160 in different control units 100 may share a same initial phase of vibration and a same frequency of vibration (i.e., vibration frequency). In some other embodiments, the diaphragms 160 in different control units 100 may have different initial phases of vibration, different frequencies of vibration, and/or different amplitudes of vibration, and the vibration conditions of the diaphragms 160 in different control units 100 may be adjusted according to actual requirements.

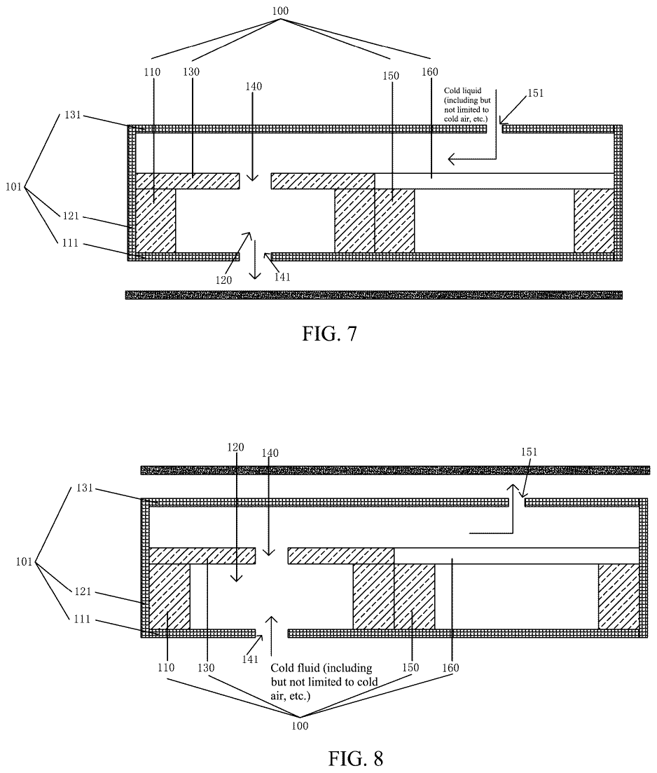

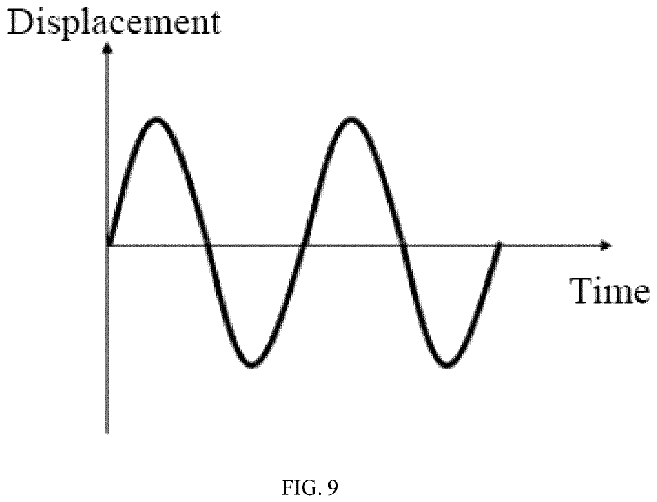

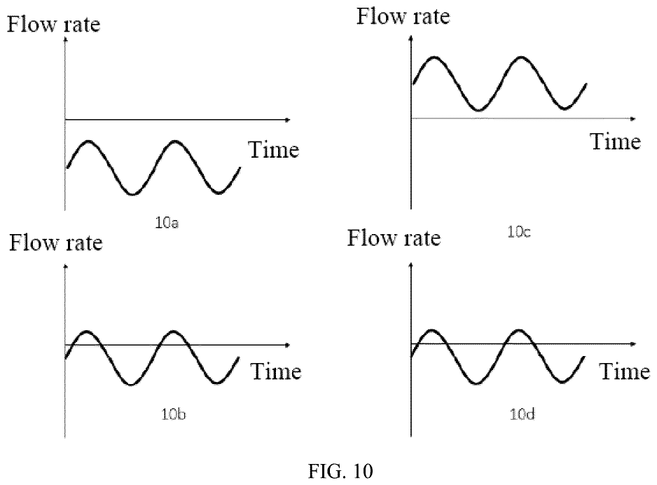

The following will describe in detail the working process of the MEMS controller when it performs heat dissipation in combination with FIG. 7 to FIG. 10. FIG. 7 is a schematic diagram of a structure of a first flow channel port as an outlet of a fluid. FIG. 8 is a schematic diagram of a structure of a second flow channel port as an outlet of a fluid. FIG. 9 is a time domain diagram of a displacement of a center of a diaphragm. FIG. 10 is a time domain diagram of a flow rate of a fluid flowing out from a second flow channel port.

Referring to FIG. 7, FIG. 9 and FIG. 10, when the MEMS controller needs to dissipate heat, the diaphragm 160 is controlled to vibrate, and the cold fluid flows in from the second flow channel port 151, passes through the second gap 140 and the first gap 120 in sequence, and flows out from the first flow channel port 141. The first flow channel port 141 can directly face the structure that needs heat dissipation, so that the cold fluid hits a surface of the structure that needs heat dissipation to complete the heat dissipation and cooling process.

In some embodiments, the vibration of the diaphragm 160 in the control unit 100 satisfies: dₛ=d₁Sin(2πf₀t), where d₁ represents an amplitude of the vibration of the diaphragm 160, and f₀ represents an operating frequency of the MEMS controller.

In some embodiments, during the operation of the MEMS controller, the vibration of the cantilever beam structure 130 can also be controlled, and the vibration of the cantilever beam structure 130 satisfies: dₛ=d₁Sin(2πf₀t+Δφ), where Δφ represents an initial phase difference between the vibration of the cantilever beam structure 130 and the vibration of the diaphragm 160 in the same control unit 100.

Referring to FIG. 10, when the cantilever beam structure 130 is not vibrating, the flow time domain diagram of the fluid flowing into the second flow channel port 151 may be as shown in FIG. 10a; or when the vibration of the cantilever beam structure 130 does not interfere with the effect of the vibration of the diaphragm 160, the flow time domain diagram of the fluid flowing into the second flow channel port 151 may be as shown in FIG. 10a. When the cantilever beam structure 130 vibrates and interferes with the effect of the vibration of the diaphragm 160, the flow time domain diagram of the fluid flowing into the second flow channel port 151 may be as shown in FIG. 10b.

According to some embodiments of the present disclosure, the unidirectional flowing of the fluid can be controlled by the MEMS controller, and the speed of the fluid flowing into the second flow channel port 151 can be no less than 20 m/s.

Referring to FIG. 8 to FIG. 10, when the MEMS controller needs to perform heat dissipation, the diaphragm 160 is controlled to vibrate, and the cold fluid flows in from the first flow channel port 141, passes through the second gap 140 and the first gap 120 in sequence, and flows out from the second flow channel port 151. The second flow channel port 151 can directly face the structure that needs heat dissipation, so that the cold fluid hits a surface of the structure that needs heat dissipation to complete the heat dissipation and cooling process.

In some embodiments, the vibration of the diaphragm 160 in the control unit 100 satisfies: dₛ=d₁Sin(2πf₀t), where d₁ represents an amplitude of the vibration of the diaphragm 160, and f₀ represents an operating frequency of the MEMS controller.

In some embodiments, during the operation of the MEMS controller, the vibration of the cantilever beam structure 130 can also be controlled, and the vibration of the cantilever beam structure 130 satisfies: dₛ=d₁Sin(2πf₀t+Δφ), where Δφ represents an initial phase difference between the vibration of the cantilever beam structure 130 and the vibration of the diaphragm 160 in the same control unit 100.

Referring to FIG. 10, when the cantilever beam structure 130 is not vibrating, the flow time domain diagram of the fluid flowing out from the second flow channel port 151 may be as shown in FIG. 10c; or when the vibration of the cantilever beam structure 130 does not interfere with the effect of the vibration of the diaphragm 160, the flow time domain diagram of the fluid flowing out from the second flow channel port 151 may be as shown in FIG. 10c. When the cantilever beam structure 130 vibrates and interferes with the effect of the vibration of the diaphragm 160, the flow time domain diagram of the fluid flowing into the second flow channel port 151 may be as shown in FIG. 10d.

According to the embodiments of the present disclosure, the unidirectional flowing of the fluid can be controlled by the MEMS controller, and the speed of the fluid flowing into the second flow channel port 151 can be no less than 20 m/s.

The present disclosure does not limit the fluid. The fluid may be liquid, gas, or sound wave, etc.

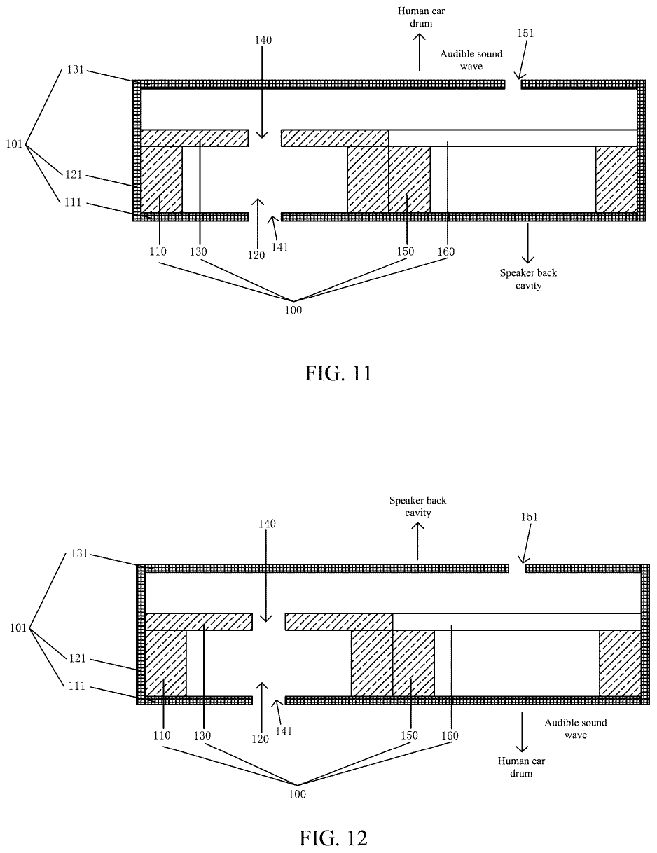

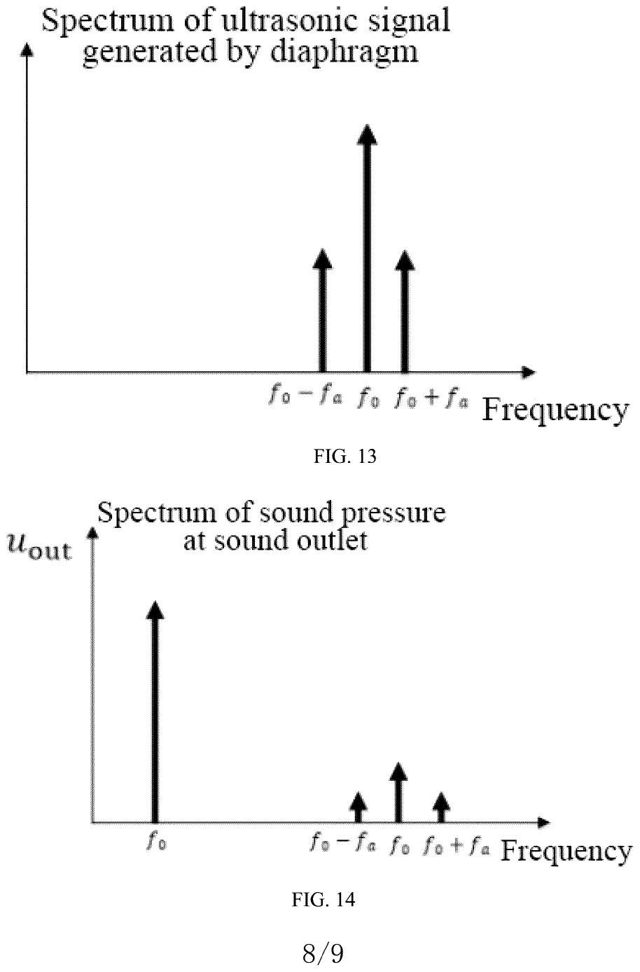

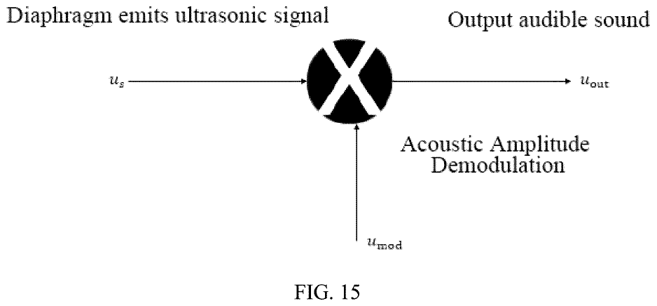

The following will describe in detail the working process of the MEMS controller when it performs sound loudspeaking in combination with FIG. 11 to FIG. 15. FIG. 11 is a schematic diagram of a structure of a second flow channel port as a sound outlet. FIG. 12 is a schematic diagram of a structure of a first flow channel port as a sound outlet. FIG. 13 is a spectrum diagram of an ultrasonic signal generated by a diaphragm. FIG. 14 is a spectrum diagram of a sound pressure at the sound outlet. FIG. 15 is a schematic diagram of a simulation structure of a loudspeaking process.

When the sound loudspeaking needs to be performed, the driving signal generated by the second anchor structure drives the diaphragm 160 to move, and the displacement of a center of the diaphragm 160 satisfies: dₛ=d₁Sin(2πf₀t)Sin(2πfₐt), where d₁ represents an amplitude of the vibration of the diaphragm 160, f₀ represents the ultrasonic frequency, and fₐ represents an audible sound frequency. After the diaphragm 160 vibrates, ultrasound will be formed, and the spectrum signal is shown in FIG. 13. The sound pressure of the ultrasound satisfies: uₛ=u₁Sin(2πf₀t)Sin(₂πfₐt), where u₁ represents the amplitude of the sound pressure. The sound channel formed by the present disclosure will perform demodulation of the sound, that is, amplitude modulation, and the amplitude modulation satisfies: u_{mod}=u₂Sin(2πf₀t), where u₂ represents an amplitude of the sound pressure. When the ultrasonic signal uₛ is modulated by the amplitude of the sound channel, an output sound pressure uₒᵤₜ is formed, and the output sound pressure satisfies: uₒᵤₜ=uₛ×u_{mod}=u₁Sin(2πf₀t)Sin(2πfₐt)×u₂Sin(2πf₀t), where × represents a multiplication symbol, and the audible sound frequency fₐ can be obtained. The spectrum diagram of the output sound pressure is shown in FIG. 14. The MEMS provided by the present disclosure can demodulate sound while being used for sound loudspeaking, thereby converting an ultrasonic frequency to be a human-audible sound frequency.

Another embodiment of the present disclosure further provides a MEMS device, which may include the MEMS controller in some or all of the above embodiments. The MEMS device provided by another embodiment of the present disclosure will be described below. It should be noted that the same or corresponding parts of the above embodiments can refer to the corresponding description of the above embodiments and will not be repeated below.

The MEMS device provided by the present disclosure can be used for heat dissipation or sound loudspeaking.

It can be understood by those skilled in the art that the above-mentioned embodiments are specific embodiments of the present disclosure, and in practical applications, various changes can be made in form and detail without departing from a spirit and a scope of the embodiments of the present disclosure. Any person skilled in the art can make various changes and modifications without departing from a spirit and a scope of the embodiments of the present disclosure, so a protection scope of the embodiments of the present disclosure shall be defined by the claims.

What is claimed is:

1. A Micro-Electro-Mechanical System (MEMS) controller, comprising:
at least one control unit, wherein the at least one control unit comprises:
two first anchor structures, a first gap being formed between two adjacent first anchor structures, and each of the two first anchor structures comprising a bottom surface and a top surface opposite to each other;
two cantilever beam structures respectively corresponding to the two first anchor structures, each of the two cantilever beam structures comprising a first end and a second end opposite to each other, the first end of each of the two cantilever beam structures being located at the top surface of the first anchor structure corresponding thereto, and a second gap being formed between the second ends of the two cantilever beam structures;
two second anchor point structures, one second anchor point structure of the two second anchor point structures being in contact with one of the two first anchor structures, and the other one of the two second anchor point structures being located at a side of the one second anchor point structure away from the two first anchor structures; and
a diaphragm covering top surfaces of the two second anchor point structures; and
an encapsulation structure comprising a bottom plate, a side plate and a top plate connected in sequence, the bottom plate directly facing the top plate, and the side plate connecting the bottom plate and the top plate,
wherein the bottom plate is located at the bottom surfaces of the two first anchor structures and the bottom surfaces of the two second anchor point structures, the bottom plate is provided with a first flow channel port penetrating through the bottom plate, the first flow channel port corresponds to the control unit, the first flow channel port is in communication with the first gap of the control unit corresponding thereto, the top plate is spaced apart from top surfaces of the two cantilever beam structures and the diaphragm, the top plate is provided with a second flow channel port penetrating through the top plate, and the second flow channel port corresponds to the control unit.

2. The MEMS controller as described in claim 1, wherein in a same control unit, a vibration frequency of at least one of the two cantilever beam structures is same as a vibration frequency of the diaphragm, and an initial phase of the at least one of the two cantilever beam structures is different from an initial phase of the diaphragm.

3. The MEMS controller as described in claim 1, wherein a distance between a center of the second flow channel port and the second end of the cantilever beam structure close to the second flow channel port is within a range from 100 μm to 5000 μm.

4. The MEMS controller as described in claim 1, wherein a height of one of the two first anchor structures is same as a height of one of the two second anchor point structures.

5. The MEMS controller as described in claim 1, wherein a height of one of the two second anchor point structures is within a range from 100 μm to 5000 μm.

6. The MEMS controller as described in claim 1, wherein a thickness of one of the two cantilever beam structures is equal to a thickness of the diaphragm.

7. The MEMS controller as described in claim 1, wherein the at least one control unit comprises two or more control units, and the two second anchor point structures in one of the control units are in contact with the two first anchor structures of an adjacent one of the control units.

8. The MEMS controller as described in claim 1, wherein the at least one control unit comprises two or more control units, one of the two second anchor point structures in one of the control units is in contact with the first anchor structure, and the other one of the two second anchor point structures in the one of the control units is in contact with the second anchor point structure of an adjacent one of the control units.

9. A MEMS device, comprising the MEMS controller as described in claim 1.
